(19) United States
(12) Patent Application Publication
(10) Pub. No.: US 2016/0270217 A1
(43) Pub. Date: Sep. 15, 2016

(54) DISPLAY DEVICE

(71) Applicant: Samsung Display Co., Ltd., Yongin-si (KR)

(72) Inventors: Sang-il Park, Yongin-si (KR); Hyun joon Oh, Seongnam-si (KR); Hye-jin Oh, Asan-si (KR); Jeoungsub Lee, Seoul (KR); Min-hoon Choi, Seoul (KR)

(21) Appl. No.: 15/052,527

(22) Filed: Feb. 24, 2016

(30) Foreign Application Priority Data
Mar. 10, 2015 (KR) 10-2015-0033362

(51) Int. Cl. H05K 1/02; G01R 27/02; G01L 1/00; H05K 5/00

(52) U.S. Cl. CPC H05K 1/0283; H05K 5/0017; G01R 27/02; G01L 1/00; H05K 2201/10151

(57) ABSTRACT

A display device is disclosed. In one aspect, the display device includes a flexible display configured to display an image and a flexible adhesive layer formed on a side of the display and configured to adhere the display to an object that is not part of the display device. The adhesive layer includes a base layer and a plurality of adhesive projections extending from an outer surface of the base layer and configured to be adhered to the object.

### CROSS-REFERENCE TO RELATED APPLICATIONS

A claim for priority under 35 U.S.C. §119 is made to Korean Patent Application No. 10-2015-0033362 filed Mar. 10, 2015, in the Korean Intellectual Property Office, the entire contents of which are hereby incorporated by reference.

### BACKGROUND

1. Field

The described technology generally relates to a display device.

2. Description of the Related Technology

As a successor technology to general display devices, various shapes of display devices are being developed. For example, flexible display devices are gradually being categorized into bendable, foldable, rollable and flexible. These display devices are designed to be transformable into preconfigured shapes or to be generally responsive to user's requirements, thus providing image information to users in diverse ways.

### SUMMARY OF CERTAIN INVENTIVE ASPECTS

One inventive aspect relates to a display device that can be easily adhered to an object.

Another aspect is a display device that includes a display part and an adhesion unit. The display part may display an image in flexibility. The adhesion unit may be flexible and formed on a surface of the display part, and the adhesion unit may adhere the display part to an object. Additionally, the adhesion unit may include a base layer and adhesive projections. The adhesive projections may be protruded from the base layer and adhered to an object.

The display part may have strechability.

The base layer and the adhesive projections may include elastomer.

Each height of the adhesive projections from the base layer may be larger than each width of the adhesive projections.

The adhesion unit may further include a first detection part to detect a flexible rate of the base layer.

The first detection part may a conductive wire and a resistance measurer. The conductive wire may be built in the base layer. The resistance measurer may be electrically connected with the conductive wire to measure resistance from the conductive wire.

The conductive wire may feature to have a shape that is twisted in the base layer.

In an embodiment of the inventive concept, the adhesion unit may further include a second detection part which is built in at least one of the base layer and the adhesive projections to detect pressure therefrom.

The second detection part may include a pressure sensor, a conductive wire, and a pressure measurer. The pressure sensor may be built in the adhesive projections, and the conductive wire may be built in the base layer and the adhesive projections and electrically connected with the pressure sensor. Additionally, the pressure measurer may be electrically connected with the conductive wire, and the pressure measurer may be provided with a sensing signal, which is generated from the pressure sensor, to measure the pressure.

Another aspect is a display device, comprising: a flexible display configured to display an image; and a flexible adhesive layer formed on a side of the display and configured to adhere the display to an object that is not part of the display device, wherein the adhesive layer comprises: a base layer; and a plurality of adhesive projections extending from an outer surface of the base layer and configured to be adhered to the object.

In the above display device, the display is stretchable. In the above display device, each of the base layer and the adhesive projections comprises an elastomer. In the above display device, each of the adhesive projections has a height that is larger than the width thereof. In the above display device, an upper portion of each of the adhesive projections is concave. In the above display device, the adhesive layer further comprises edge portions that are coupled respectively with the upper portions of the adhesive projections and extending in a widthwise direction of the adhesive projections. In the above display device, the adhesive layer further comprises a first sensor configured to detect an extension rate of the base layer.

In the above display device, the first sensor comprises: a conductive wire formed in the base layer; and a resistance measurer electrically connected to the conductive wire and configured to measure resistance from the conductive wire. In the above display device, the conductive wire is twisted in the base layer. In the above display device, the conductive wire extends over the entire area of the base layer. In the above display device, the adhesive layer further comprises a second sensor formed in at least one of the base layer and the adhesive projections and configured to detect pressure. In the above display device, the second sensor comprises: at least one pressure sensor formed in the adhesive projections; a conductive wire formed in the base layer and the adhesive projections and electrically connected to the pressure sensor; and a pressure measurer electrically connected to the conductive wire, and configured to receive a sensing signal from the pressure sensor and measure the pressure.

Another aspect is a display device, comprising: a flexible display configured to display an image; and a flexible adhesive layer formed on the flexible display and configured to adhere the display to an object that is separate from the display device, and wherein the flexible adhesive layer is further configured to conform its shape to an outer surface of the object when adhered. In the above display device, the adhesive layer comprises: a base layer; and a plurality of adhesive projections extending from an outer surface of the base layer and configured to be adhered to the object.

In the above display device, each of the base layer and the adhesive projections is formed of an elastomer. In the above display device, each of the adhesive projections has a cylindrical shape, and wherein the top surface of each adhesive projection is concave. In the above display device, each of the adhesive projections has a height larger than the width thereof. In the above display device, the adhesive projections are spaced apart from each other, and wherein the adhesive projections have substantially the same height. In the above display device, the object has an uneven, non-linear or curved outer surface. In the above display device, the object is an interior component of an automobile.

According to at least one of the disclosed embodiments, adhesive projections of an adhesion unit may be implemented with microscopic cilia of a gecko in biomimetics. As a result, the adhesive projections may be used for simply adhering a display part to a surface of an object. Additionally, although the surface of the object is uneven, the display part may be adhered to the surface by topological properties of the adhesive projections.

Additionally, by providing various types of detection parts into the adhesion unit, it may be permissible to easily detect an extension rate of the display part and pressure that is applied on the display part.

### BRIEF DESCRIPTION OF THE DRAWINGS

FIGS. 1A and 1B are diagrams illustrating stretchability of a display device according to an embodiment.

FIG. 2 is a diagram illustrating an adhesive state of the display device shown in FIG. 1A.

FIG. 3A is an explosive diagram illustrating the rear side of the display device shown in FIG. 1A.

FIG. 3B is a sectional diagram taken by I-I′ of FIG. 3A.

FIG. 4A is an explosive diagram illustrating the rear side of a display device according to another embodiment.

FIG. 4B is a sectional diagram taken by II-II′ of FIG. 3A.

FIG. 5A is an explosive diagram illustrating the rear side of a display device according to another embodiment.

FIG. 5B is a sectional diagram taken by of FIG. 5A.

FIG. 6 is a sectional diagram illustrating a display device according to another embodiment.

FIG. 7 is a sectional diagram illustrating a display device according to another embodiment.

FIG. 8 is a sectional diagram illustrating a display device according to another embodiment.

### DETAILED DESCRIPTION OF CERTAIN INVENTIVE EMBODIMENTS

Advantages and features of the inventive concept, and ways for accomplishing them will be apparent from embodiments described in detail hereinafter in conjunction with the accompanying drawings. The inventive concept, however, may be applicably embodied in various different forms, and may not be construed as being limited only to the illustrated embodiments. Rather, these embodiments described herein are provided as examples so that this disclosure will be thorough and complete, and will fully convey the concept of the described technology to those skilled in the art. Therefore, the scope of the described technology may not be restrictive to the embodiments described below. Unless otherwise noted, the same reference numerals denote the same elements throughout the attached drawings.

It will be understood that, although the terms “first”, “second”, “third”, etc., may be used herein to differentiate one element from another elements. Additionally, as used herein, when there is a description that a part like film, area or region, or element is placed ‘over’ or ‘on’ another part, such a description may be construed as including another film, area, or element which is intermediate between them, as well as including a structure that such a film, area, or element is placed directly on another part.

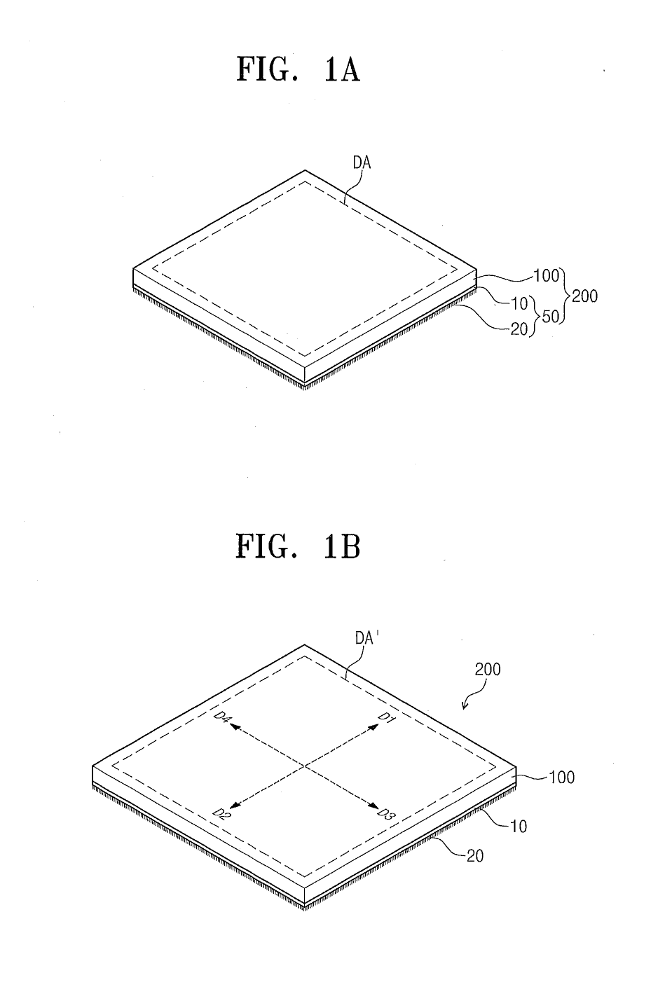

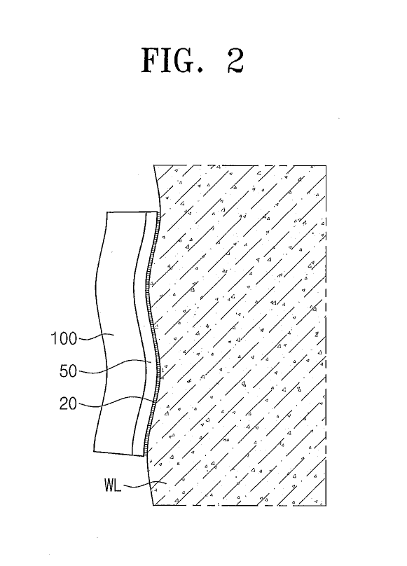

FIGS. 1A and 1B are diagrams illustrating stretchability of a display device according to an embodiment, and FIG. 2 is a diagram illustrating an adhesive state of the display device shown in FIG. 1A.

Referring to FIGS. 1A, 1B, and 2, the display device 200 includes a display part (or display) 100 and an adhesion unit (or adhesive layer) 50. The display part 100 may display an image through a display area DA, and the adhesion unit 50 may adhere the display part 100 to an object WL. The object can be an automobile or a component of the automobile. For example, the component can be an interior component of the automobile such as a dashboard or a console box. In other embodiments, the object can be other devices having an uneven, non-linear or curved outer surface.

The display part 100 may have flexibility. In this embodiment, the display part 100 may include at least one base plate having stretchability for flexibility. For example, the base plate may comprise an elastomer such as polydimethysiloxane (PDMS).

Additionally, although not shown, in this embodiment, the display part 100 may include a multiplicity of wires formed on the base plate, and a multiplicity of pixels electrically connected with the multiplicity of wires.

The multiplicities of wires and pixels may have shapes corresponding to stretchability of the base plate. For example, if the multiple wires are formed in a shape of straight line on the base plate while the base plate is extended, the multiplicity of wires may be shaped in zigzag while the base plate is shrunk.

In this embodiment, the display part 100 may include an organic electro-luminescence display panel. With this configuration, the display part 100 may include a base plate, multiplicities of wires and pixels formed on the base plate, and a sealing member to seal the multiplicity of pixels. Each pixel may include an anode, a cathode, and an organic luminescent layer.

In another embodiment, the display part 100 may include a liquid display panel, and the display part 100 may include a pair of two base plates facing each other, multiplicities of wires and pixels formed on one of the two base plates, and a liquid crystal layer interposed between the two base plates.

The adhesion unit 50 may be formed on the rear side of the display panel 100 to adhere the display panel 100 to an object WL. In this embodiment, the adhesion unit 50 may include a base layer 10, and adhesive projections 20 protruded from the base layer 10.

The adhesion unit 50 may have flexibility. In this embodiment, the base layer 10 and the adhesive projections 20 may contain the same material. The base layer 10 and the adhesive projections 20 may comprise an elastomer such as polydimethysiloxane (PDMS) for flexibility.

As aforementioned, as the display part 100 and the adhesion unit 50 have flexibility, the display device 200 may be extended toward at least one direction and shrunk in the reverse of the extending direction.

For example, as shown in FIG. 1B, if external force is applied to the display device 200, a part of the display device 200 may extend in a first direction D1. Additionally, if the external force is removed from the display device 200, the part of the display device 200, which has extended in the first direction D1, may shrink in a second direction D2 that is the reverse of the first direction D1.

External force may be also applied to make the other part of the display device 200 extend in a third direction D3. Then, if the external force is removed from the display device 200, the other part of the display device 200, which has extended in the third direction D3, may shrink in a fourth direction that is the reverse of the third direction D3.

Accordingly, assuming that the display part 100 has the display area DA while the display device 200 is being in a shrunk state, the display part 100 may have a display area DA′ which extend while the display device 200 is being in an extended state. Resultantly, the display device 200 may provide a further enlarged image to a user through the display area DA′ which is extended from the display area DA.

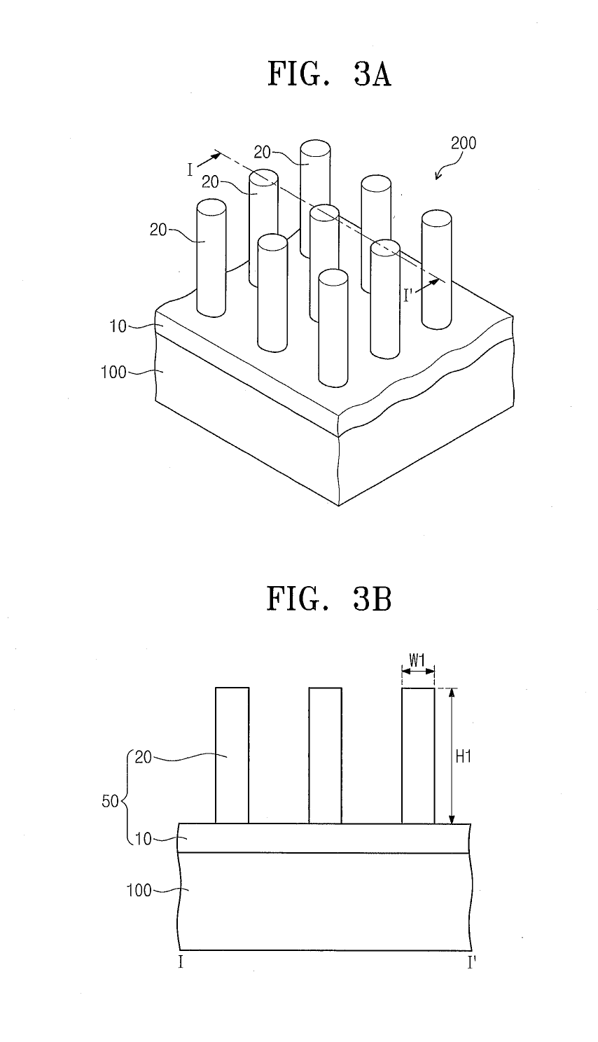

The display device 200 may be adhered to an outer surface 5 of the object WL by the adhesion unit 50. Additionally, even if the outer surface 5 is uneven, this embodiment may be implemented to allow the display device 200 to easily adhere to the outer surface 5 on the topological advantage of the adhesion unit 50. The structure of the adhesive unit 50 will be described in conjunction with FIGS. 3A and 3B.

FIG. 3A is an explosive diagram illustrating the rear side of the display device shown in FIG. 1A and FIG. 3B is a sectional diagram taken by I-I′ of FIG. 3A.

Referring to FIGS. 3A and 3B, the adhesion unit 50 may include the base layer 10, and the adhesive projections 20 which are protruded from the base layer 10.

In this embodiment, the adhesive projections 20 may be formed with a density in a range from about 10,000 cm/² to about 20,000 /cm² on the base layer 10.

Assuming that each height and each width of the adhesive projections 20 are defined respectively as H1 and W1, the height H1 may be larger than the width W1 in dimensions. In this embodiment, the height H1 may be ranged about 500 nm (nanometers) to about 5,000 μm (micrometers) and the width W1 may be ranged about 100 nm to about 1,000 μm. However, in another embodiment, the dimensions respective to the width W1 and the height H1 may be modified in accordance with a size or weight of the display part 100.

The adhesive projections 20 may be an example using biomimetics. More specifically, the adhesive projections 20 may be implemented from microscopic cilia which are found in soles of a gecko. The adhesion unit 50 may be equipped with adhesiveness by the adhesive projections 20. This adhesiveness may arise from the van der Waals force that acts between the adhesive projections 20 and the object WL. Thus, as a contact area between the adhesive projections 20 and an outer surface (5 of FIG. 2) of an object (WL of FIG. 2) becomes larger, the adhesiveness may increases in strength.

Additionally, since the display part 100 adheres to the object WL in the aforementioned mechanism, the display part 100 may be simply detached from the object WL and thereby it may be allowable to prevent an adhesive material from remaining on the object WL while the display part 100 is being detached from the object WL.

Additionally, since the display part 100 adheres to the object WL in the aforementioned mechanism, it may be allowable to prevent the strength of adhesiveness from weakening between the display part 100 and the object WL even though an adhering operation is repeated between the display part 100 and the object WL.

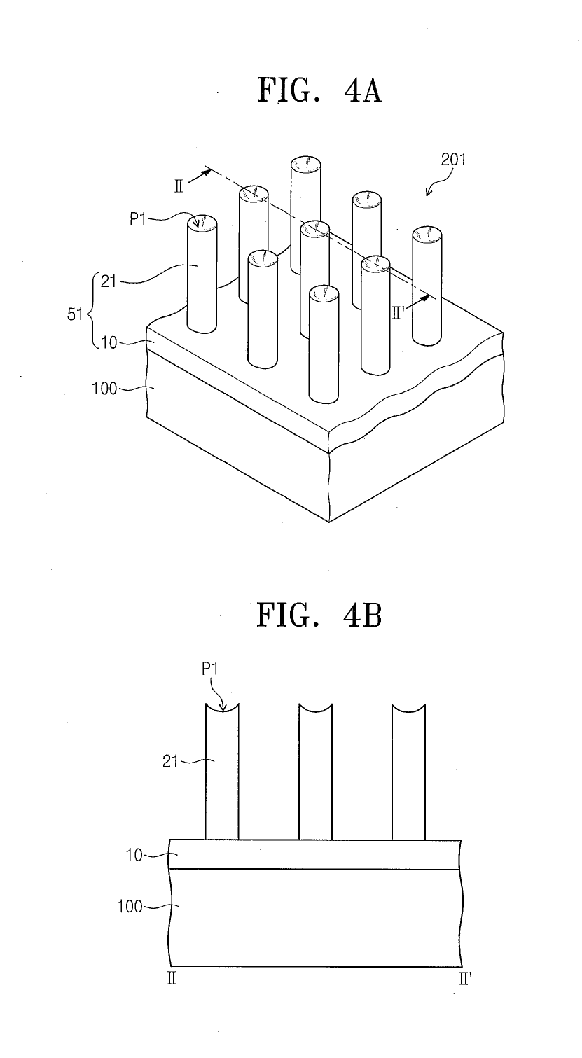

FIG. 4A is an explosive diagram illustrating the rear side of a display device 201 according to another embodiment, and FIG. 4B is a sectional diagram taken by II-II′ of FIG. 3A, In description with FIGS. 4A and 4B, the elements explained above will be numbered in parallel with their formers and so will not be further explained.

Referring to FIGS. 4A and 4B, the display device 201 includes a display part 100 and an adhesion unit 51. The adhesion unit 51 may include a base layer 10, and adhesive projections 21 protruded from the base layer 10.

In this embodiment, each upper part P1 of the adhesive projections 21 may have a concave shape. Accordingly, if the adhesion unit 51 is compressed on an object (WL of FIG. 2), there may be generated vacuum pressure between the upper part P1 and an outer surface (5 of FIG. 2) while the upper part P1 is being pressed on the outer surface.

Therefore, in addition to the van der Waals force acting between the adhesive projections 21 and the object WL, as the vacuum pressure further help the display device 201 to adhere the display device 201 to the object WL, the adhesiveness may increase between the display device 201 and the object WL.

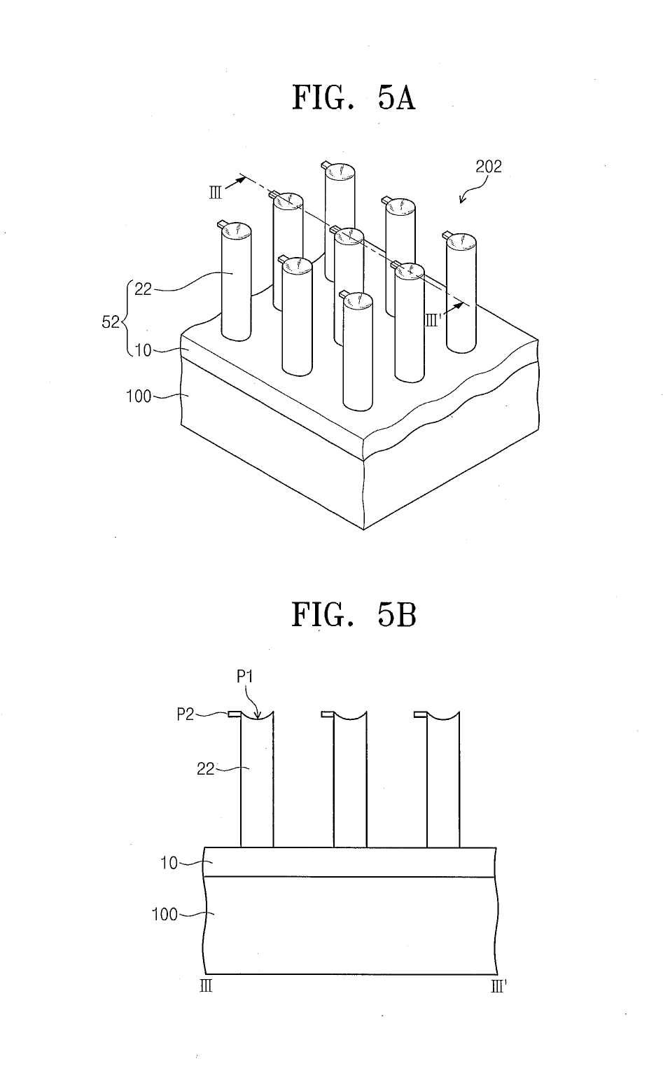

FIG. 5A is an explosive diagram illustrating the rear side of a display device 202 according to another embodiment, and FIG. 5B is a sectional diagram taken by III-III′ of FIG. 5A. In description with FIGS. 5A and 5B, the aforementioned elements will be referred by the same numerals or signs, so will not be further explained.

Referring to FIGS. 5A and 5B, the display device 202 includes a display part 100 and an adhesion unit 52. The adhesion unit 52 may include a base layer 10, and adhesive projections 22 which are protruded from the base layer 10.

In this embodiment, the adhesion unit 52 may include edge parts P2 which are coupled respectively with the upper parts P1 of the adhesive projections and extended in a widthwise direction of the adhesive projections. As aforementioned, the upper part P1 may be shaped in a concave while the edge part P2 may be shaped in a flat.

With the structure of the adhesive projections 22, the concave shape of the adhesive projections causes vacuum pressure to be generated between the upper parts P1 and an object (WL of FIG. 2), the edge parts P2 may not contribute to the generation of vacuum pressure because the edge parts P2 have flat shapes. The edge parts P2 may contact, namely, with the object face to face, and thereby may be easily detached from the object more than the upper parts P1.

Therefore, according to this embodiment, the adhesive projections 22 may include the upper parts P1 and the edge parts P2 to improve adhesiveness of the adhesive projections 22 and ease even a work of detaching the adhesive projections 22, which have adhered to the object, from the object.

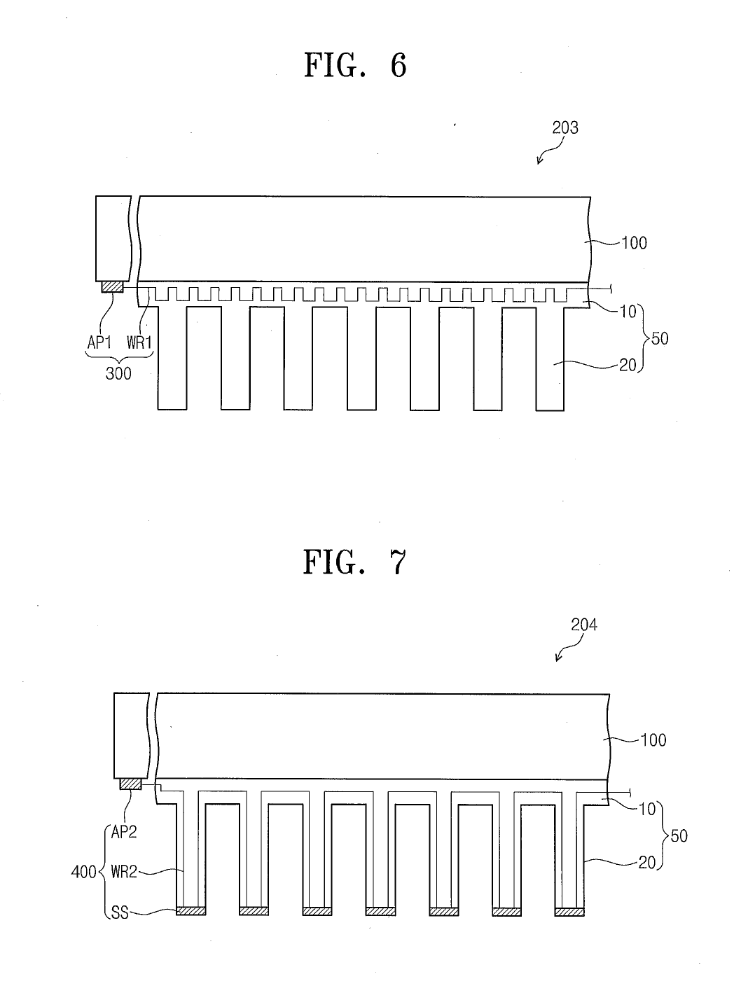

FIG. 6 is a sectional diagram illustrating a display device 203 according to another embodiment. In description with FIG. 6, the aforementioned elements will be referred by the same numerals or signs, so will not be further explained.

Referring to FIG. 6, the display device 203 includes a display part 100, an adhesive unit 50, and a first sensing part 300. In this embodiment, the first sensing part 300 may include a first conductive wire WR1 and a resistance measurer AP1.

The conductive wire WR1 may be built in a base layer 10 of the adhesion unit 50. In this embodiment, the first conductive wire WR1 may extend over the total area of the base layer 10. Accordingly, if the base layer 10 extends or shrinks, the first conductive wire WR1 may extend or shrink along with the base layer 10.

In this embodiment, the first conductive wire WR1 may contain a conductive material such as carbon nanotube or graphene.

The resistance measurer AP1 may be electrically connected with the first conductive wire WR1 to measure resistance from the first conductive wire WR1. In more detail, a state that the display device 203 extends as shown in FIG. 1B may be defined as a first state. A state that the display device 203 shrinks as shown in FIG. 1A may be defined as a second state. With this configuration, the length of the first conductive wire WR1 may be longer in the first state than in the second state. As a result, first resistance of the first conductive wire WR1 in the first state may be larger than second resistance of the first conductive wire WR1 in the second state.

In the meantime, an extension rate of the base layer 10 of the adhesion unit 50 may be estimated based on a difference between values of the first and second resistance. Additionally, as the display part 100 extends or shrinks along with the base layer 10, an extension rate of the display part 100 may be estimated based on the extension rate of the base layer 10 which can be estimated by the resistance measurer AP1.

Therefore, according to the aforementioned structure and functions of the first sensing part 300, resistance of the first conductive wire WR1, which is obtained by the resistance measurer AP1, may be used to indirectly detect an extension or shrinkage rate of the display part 100.

Additionally, if information about resistance or an extension or shrinkage rate of the display part 100, which is calculated based on the resistance, is indicated in a display area (DA of FIG. 1A), a user may refer the information to handle the display device 203. For example, if the display device 203 is used to further extend the display device 203 in a rate larger than a predetermined rate, a user may be able to refer the information to shrink the display device 203 to reduce an extension rate of the display device 203.

In this embodiment, the first conductive wire WR1 may be twisted in the base layer 10. With this configuration, the first conductive wire WR1 built in the base layer 10 may be enlarged in length by the twisted shape. Accordingly, corresponding to the extension of the base layer 10, a length of the conductive wire WR may increase to raise resistance, which varies along the length, in displacement. As a result, corresponding to the increased displacement of the resistance, it may be allowable to improve sensitivity of the sensing part 300.

FIG. 7 is a sectional diagram illustrating a display device 204 according to another embodiment. In description with FIG. 7, the aforementioned elements will be referred by the same numerals or signs, so will not be further explained.

Referring to FIG. 7, the display device 204 includes a display part 100, an adhesion unit 50, and a second sensing part 400. In this embodiment, the second sensing part 400 may include pressure sensors SS, a second conductive wire WR2, and pressure measurer AR2.

The pressure sensors SS may be built in adhesive projections 20 of the adhesion unit 50. In this embodiment, the pressure sensors SS may be placed at ends of the adhesion projections 20. The pressure sensors SS may detect pressure that is externally applied toward the display device 204, and generate sensing signals in correspondence with the detected pressure.

In this embodiment, the pressure sensors SS may be one type of piezoelectric pressure sensors, optical pressure sensors, capacitive pressure sensors, and semiconductor pressure sensors.

The second conductive wire WR2 may be electrically connected with the pressure sensors SS. In this embodiment, the second conductive wire WR2 may be built in the base layer 10 and the adhesive projections 20 of the adhesion unit 50. In this embodiment, the second conductive wire WR2 may be shaped to extend along each lengthwise direction of the adhesive projections 20 in each inside of the adhesive projections 20, and extend over the total area of the base layer 10 in the inside of the base layer 10 of the adhesion unit 50.

In this embodiment, the second conductive wire WR2 may contain a conductive material such as carbon nanotube or graphene. In another embodiment, the second conductive wire WR2 may contain a metal such as copper.

Meanwhile, if the sensing signal is generated from the pressure sensors SS in response to pressure that is externally applied toward the display device 204, the sensing signal may be provided toward a pressure measurer AP2 through the second conductive wire WR2. The pressure measurer AP2 may be electrically connected with the second conductive wire WR2 and thereby provided with the sensing signal from the pressure sensors SS.

As shown in FIG. 2, a first part of the display device 204 may be defined at a convex area of an outer surface (5 of FIG. 2) of an object (WL of FIG. 2) which adheres to the display device 204, while a second part of the display device 204 may be defined at a concave area of the object WL which adhere to the display device 204. With this definition, if the display device 204 is pressed to adhere to the object WL, the pressure measurer AP2 may measure pressure that is applied respectively to the first part and the second part. Pressure applied to the first part may be larger than pressure applied to the second part. In other words, pressure taken from the first and second parts by the pressure measurer AP2 may be used for estimating curvatures of the areas contacting with the first and second parts in the outer surfaces.

In this embodiment, information about the measured pressure or the curvatures of the areas contacting with the first and second parts may be displayed in a display area (DA of FIG. 1A). During this, a user may be able to the information in handling the display device 204. For example, if the display device 204 is pressured with a value larger than a predetermined value, the information may be referred by a user to reduce the current pressure that is applied to the display device 204.

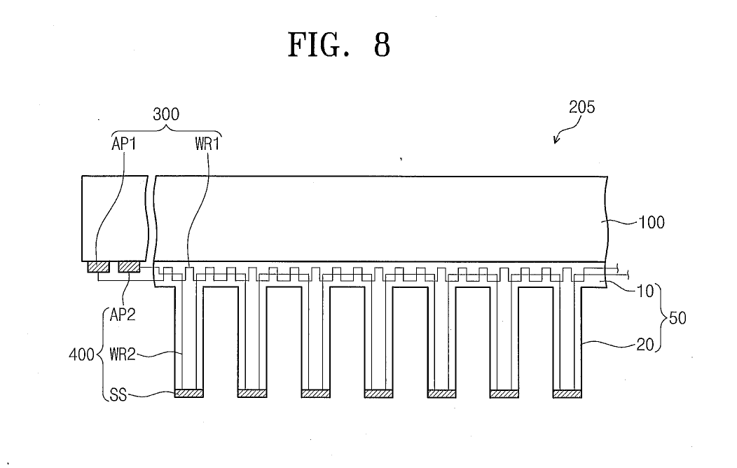

FIG. 8 is a sectional diagram illustrating a display device 205 according to another embodiment. In description with FIG. 8, the aforementioned elements will be referred by the same numerals or signs, so will not be further explained.

Referring to FIG. 8, the display device 205 may include a display part 100, an adhesion unit 50, a first sensing part 300, and a second sensing part 400.

The display device 205 according to this embodiment may include the first sensing part 300 which is described in conjunction with FIG. 6, and the second sensing part 400 which is described in conjunction with FIG. 7. Accordingly, the display device 205 may detect an extension rate of the display device 205, detect pressure that is applied to the display device 100, and detect a surface curvature of an object to which the display device 205 adheres.

While the inventive technology has been described with reference to exemplary embodiments, it will be apparent to those skilled in the art that various changes and modifications may be made without departing from the spirit and scope of the inventive concept set forth throughout the annexed claim matters. Therefore, it should be understood that the above embodiments are not limiting, but illustrative, hence all technical things within the annexed claims and the equivalents thereof may be construed as properly belonging to the territory of the inventive concept.

What is claimed is:

1. A display device, comprising:
a flexible display configured to display an image; and
a flexible adhesive layer formed on a side of the display and configured to adhere the display to an object that is not part of the display device,
wherein the adhesive layer comprises:
a base layer; and
a plurality of adhesive projections extending from an outer surface of the base layer and configured to be adhered to the object.

2. The display device according to claim 1, wherein the display is stretchable.

3. The display device according to claim 1, wherein each of the base layer and the adhesive projections comprises an elastomer.

4. The display device according to claim 1, wherein each of the adhesive projections has a height that is larger than the width thereof.

5. The display device according to claim 4, wherein an upper portion of each of the adhesive projections is concave.

6. The display device according to claim 5, wherein the adhesive layer further comprises edge portions that are coupled respectively with the upper portions of the adhesive projections and extending in a widthwise direction of the adhesive projections.

7. The display device according to claim 1, wherein the adhesive layer further comprises a first sensor configured to detect an extension rate of the base layer.

8. The display device according to claim 7, wherein the first sensor comprises:
a conductive wire formed in the base layer; and
a resistance measurer electrically connected to the conductive wire and configured to measure resistance from the conductive wire.

9. The display device according to claim 8, wherein the conductive wire is twisted in the base layer.

10. The display device according to claim 9, wherein the conductive wire extends over the entire area of the base layer.

11. The display device according to claim 1, wherein the adhesive layer further comprises a second sensor formed in at least one of the base layer and the adhesive projections and configured to detect pressure.

12. The display device according to claim 11, wherein the second sensor comprises:
at least one pressure sensor formed in the adhesive projections;
a conductive wire formed in the base layer and the adhesive projections and electrically connected to the pressure sensor; and
a pressure measurer electrically connected to the conductive wire, and configured to receive a sensing signal from the pressure sensor and measure the pressure.

13. A display device, comprising:
a flexible display configured to display an image; and
a flexible adhesive layer formed on the flexible display and configured to adhere the display to an object that is separate from the display device, and wherein the flexible adhesive layer is further configured to conform its shape to an outer surface of the object when adhered.

14. The display device according to claim 13, wherein the adhesive layer comprises:
a base layer; and
a plurality of adhesive projections extending from an outer surface of the base layer and configured to be adhered to the object.

15. The display device according to claim 13, wherein each of the base layer and the adhesive projections is formed of an elastomer.

16. The display device according to claim 13, wherein each of the adhesive projections has a cylindrical shape, and wherein the top surface of each adhesive projection is concave.

17. The display device according to claim 13, wherein each of the adhesive projections has a height larger than the width thereof.

18. The display device according to claim 13, wherein the adhesive projections are spaced apart from each other, and wherein the adhesive projections have substantially the same height.

19. The display device according to claim 13, wherein the object has an uneven, non-linear or curved outer surface.

20. The display device according to claim 13, wherein the object is an interior component of an automobile.
